(19) United States
(12) Patent Application Publication
(10) Pub. No.: US 2007/0278556 A1
(43) Pub. Date: Dec. 6, 2007

(54) Two bits non volatile memory cells and method of operating the same

(76) Inventors: Ya-Chin King, Taipei (TW); Chrong-Jung Lin, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/442,119

(22) Filed: May 30, 2006

(51) Int. Cl. H01L 29/788

(52) U.S. Cl. 257/315

(57) ABSTRACT

A twin non-volatile memory cell on unit device and method of operating the same are disclosed. The device is formed in the n-well and compatible with CMOS processes comprising a selecting gate, two ONO spacers, a p+ source/drain, and n extended source/drain. To program the cells, two strategies can be taken. One is by a band to band hot electron injection can be carried out. The other is by channel hot hole induced hot electron injection. To read the right cell of the twin nonvolatile cells, a reverse read is taken so as to shield the left cell. In the reading process, the biased on the selecting gate and the source electrode have to make sure the tapered main channel beneath selecting gate has its narrower end through the depletion boundary to connect the second channel beneath the extended source. To erase the datum in the selected cell, two approaching can be carried out. One is by FN erase, the other is by band to band induced hot hole injection.

### FIELD OF THE INVENTION

The present invention relates to a nonvolatile memory structure, specifically, to a device having twin flash memory cells formed thereon and a method of operating the same.

### BACKGROUND OF THE INVENTION

Flash disk is a kind of nonvolatile data storage apparatus. Once the data are stored, the lifetime of the data is at least over ten years without any electric energy to keep the data therein. To access data, it needs exerts voltages at individually electrodes only depends on what the operations are. By contrast, for hard disk apparatus, a stepping motor to carry magnetic read/write head flying on the magnetic disk is necessary. Hence, for flash disk, no mechanical vibrating problem is required to be considered. Furthermore, with fast progressing of semiconductor manufacture technique, an occupation volume of a flash disk is small significantly than that of a hard disk apparatus, for the same memory capacity is concerned. Consequently, the flash disk is a kind of high portable apparatus and widely used as a thumb disk, MP3 player, PDA (personal digital assistance), mobile phone, digital still camera, and a variety of memory cards. The applications of the memory card are even more, such as memory expansion for above hand held appliance and personal computer, and home electrical appliance.

Generally, a flash memory cell includes a control gate, a floating gate, a source/drain. When a cell is programmed so that its floating gate captures electrons in it, the datum stored according to the binary code in the cell is called “0” or called “1” if the floating gate has none electron during programming.

What a big memory capacity a flash disk apparatus is, it's surely dependent on how many flash chips it stacked and each capacity of the flash chip has. The more advance of a semiconductor fabricating technique is, the more capacity a flash chip will be. For instance as a device is scaling down by one half, the memory size will be increased by about four times. For current semiconductor processes, the size of a chip about a thumb nail having a memory capacity of about one gaga bytes (1 G) is not unusual. The capacity is over a 5½ inch large hard disk at ten years ago. Surely, the hard disk apparatus is not a feeble competitor in the memory storage market. Nowadays, not only is a 2½″ hard disk commonly used in the notebook computer, but also a mini hard disk. storage apparatus or MP3 player of about 1″ in size having capacity of about 60 G is developed.

Thus to avoid the flash disk being eliminated through memory storage competition, the semiconductor manufacturing engineers are not merely pursuing the device scaling down, a better device structure of a memory cell is also desired. Recently, a novel nonvolatile cell called SONOS is a successful exemplary.

FIG. 1A and FIG. 1B represent, respectively, cross-sectional views of a split gate flash 5 and a stack gate flash 5. The common feature is the floating gate is formed of a polycrystalline silicon layer. Once the electrons are injected into the floating gate 10 of the flash cell 5, the electrons will be distributed evenly in the floating gate 10. Thus, a floating gate formed of polycrystalline silicon, the cell can only store one bit datum only.

Whereas, a SONOS (semiconductor, oxide, nitride, oxide, and semiconductor) flash 20 is different. Referring to FIG. 1C, it is like a stack gate flash 5 shown in 1B). In the SONOS cell, a silicon nitride layer 23 is substitute for the poly-Si layer 10. Since the nitride layer 23 is enclosed by oxide cladding layers 22, 24 and all of them are a dielectric material. Therefore, a SONOS is also like a conventional transistor having an ONO layer rather than one oxide layer. However, once electrons are captured or injected into the nitride layer 23, the electrons will be confined at a localized region due to their much lower mobility the nitride layer can provide. Consequently, if the electrons are injected from the source electrode 21, then the electrons will be localized at a region 23a closed to the source region 21 and if the electrons are injected from the drain electrode 24, then the electrons will be localized at a region 23b closed to the drain region 24. On the other word, a device can record two bits if it is appropriate operated. The capacity of a device is thus doubled under the same semiconductor scaling technique.

### SUMMARY OF THE INVENTION

An object of the present invention is to double non-volatile memory capacity without further scaling down the semiconductor device.

Another object of the present invention is to form a novel nonvolatile memory, which is compatible with an analog CMOS processes.

The present invention disclosed a pMOS based nonvolatile twin cells and the method of operating the same. The device is formed in the n-well and compatible with CMOS processes comprising a selecting gate, two ONO spacers, a p+ source/drain, and n extended source/drain. To program the cells, two strategies can be taken. One is by a band to band hot electron injection can be carried out. The other is by channel hot hole induced hot electron injection. To read the right cell of the twin nonvolatile cells, a reverse read is taken so as to shield the left cell. In the reading process, the biased on the selecting gate and the source electrode have to make sure the tapered main channel beneath selecting gate has its narrower end through the depletion boundary to connect the second channel beneath the extended source. To erase the datum in the selected cell, two approaching can be carried out. One is by FN erase, the other is by band to band induced hot hole injection.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A illustrates a cross-sectional view of a split gate flash according to prior art.

FIG. 1B illustrates a cross-sectional view of a stack gate flash according to prior art.

FIG. 1C illustrates a cross-sectional view of a SONOS nonvolatile memory cell according to prior art.

FIG. 2A. shows a structure of pMOS based nonvolatile twin cells according to the present invention.

FIG. 2B. shows programming a right cell of the pMOS based nonvolatile twin cells by band to band hot electron injection according to the present invention.

FIG. 2C. shows reading a right cell of the pMOS based nonvolatile twin cells by a reverse read method according to the present invention.

FIG. 2D. shows erasing a right cell of the pMOS based nonvolatile twin cells by FN method to pull out the electron in the nitride layer according to the present invention.

FIG. 2E. shows erasing a right cell of the pMOS based nonvolatile twin cells by band to band hot hole injection according to the present invention.

FIG. 3 shows a structure of nMOS based nonvolatile twin cells according to the present invention.

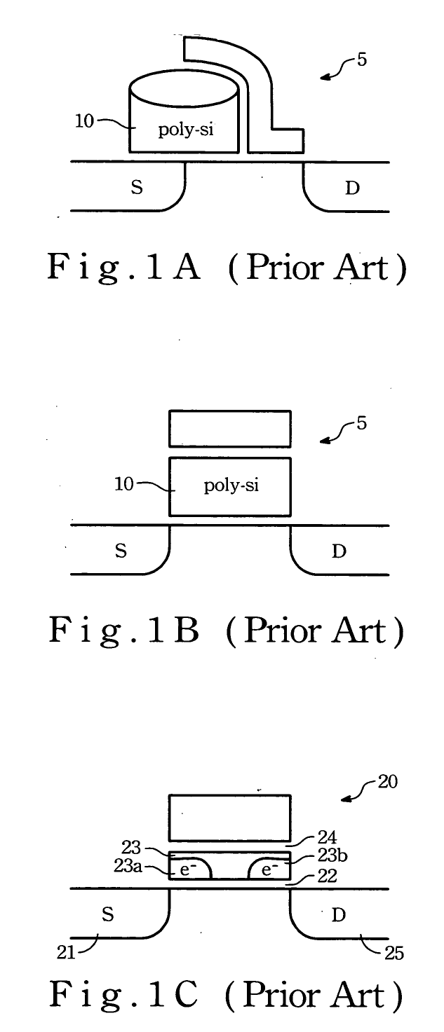

### DETAILED DESCRIPTION OF THE PREFERRED EMBODIMENT

In a preferred embodiment, the present invention is to provide twin novel SONOS flash cells of which fabricating processes are completely compatible with those of analog CMOS (complementary metal oxide semiconductor transistor) processes. The two ONO spacers each having a nitride layer 220A (or 220B) served as a floating gate of a nonvolatile cell, are constructed at the sidewalls of a pMOS. The pMOS serves as a selected gate associated with individually voltages exerted at the source/drain and the body of the pMOS, a right floating gate, assuming it is formed at a drain side or a left floating gate formed at a source side can be appropriated selected and operated.

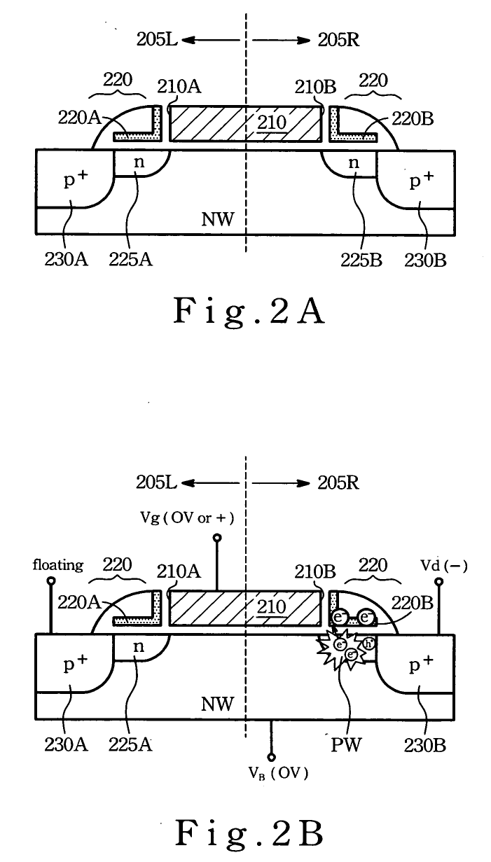

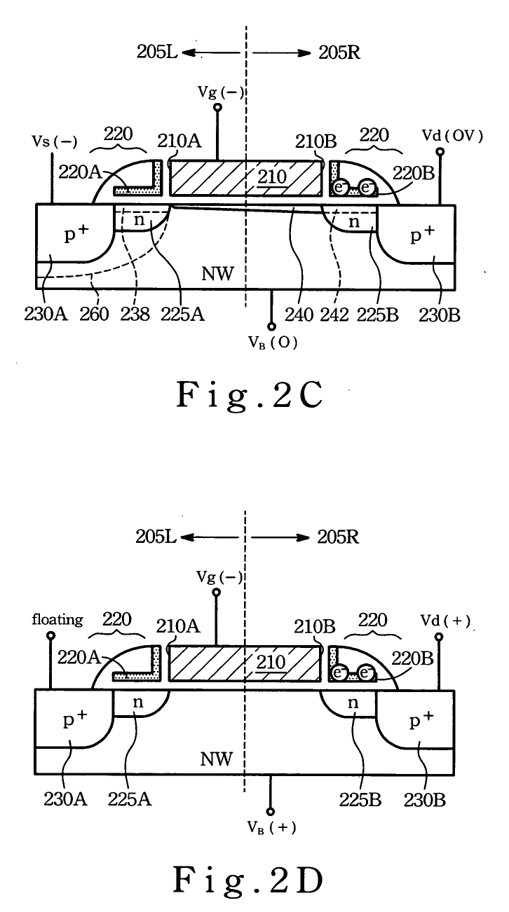

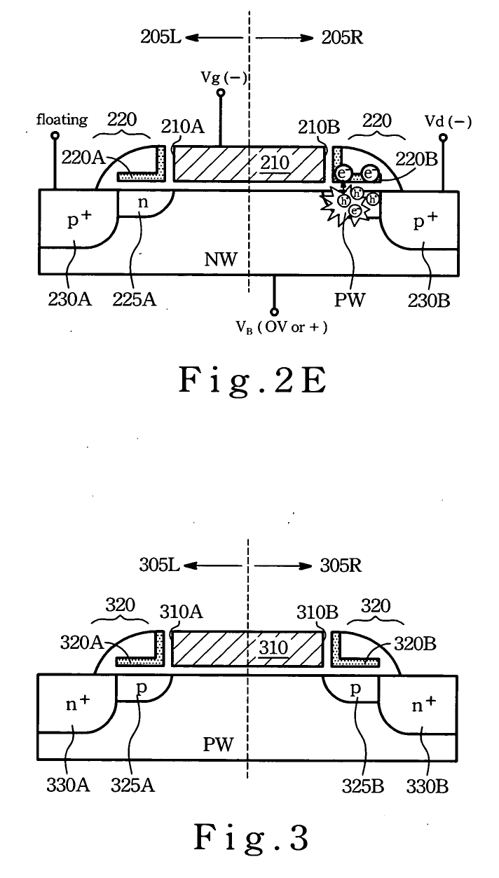

The pMOS based twin nonvolatile cells 205L, 205R are constructed in a n-well NW of a CMOS process. Please refer to FIG.2A, a cross-sectional view. It includes a selecting gate 210, two sidewalls 210A, 210B, ONO spacers 220 having, respectively, a L-mirror and a L shaped nitride layer,220A, 220B, a p+ doped source 230A/drain region 230B, and an n doped extended source 225A/drain region 225B. The impurity concentrations in the n doped extended source/drain 225A, 225B are higher than that of in n-well. Worthwhile, the impurity conductivity in the extended source/drain 225A, 225B having its conductivity type opposite to that in the source/drain 230A, 230B. The nonvolatile cell including the nitride layer 220B as a floating gate is denoted as right cell 205R or right nonvolatile cell 205R. By contrast, the nonvolatile cell including the nitride layer 220A is denoted as left cell or left nonvolatile cell 205L.

According to the present invention, the pMOS-based twin nonvolatile cells are a symmetry structure, though the source region and drain are respectively, labeled as 230A, 230B herein, the names can be exchanged. Following depictions are operations for the right nonvolatile cell 205R only, and this is an illustration of the present invention rather than limiting the claim scope thereon. Accordingly, any one who is skilled in the art will know the operation to the left nonvolatile cell 205L, thus the depictions are skipped.

For programming the right nonvolatile cell 205R, a method based on principle of band to band hot electron injection is taken.

When the right cell 205R is desired to program as 1, the voltages Vs, Vg, VB, and Vd exerted on the source electrode 230A, selecting gate 210, n-well body NW, and drain 230B are respectively, floated, 0V or a more positive voltage denoted by Vg(0V or +), 0V denoted by V_{B} (0V), and negative voltage denoted by Vd (−), as is shown in FIG. 2B. Accordingly, the drain 230B and the n-well body NW are reverse biased, as a result an electric field due to the space charges is generated in between the drain 230B and n-well NW. If the intensity of electric field is strong enough, electron-hole pairs are generated due to a Fermi level of the valence band of the p+ drain region 230B is over the Fermi level of the conduction band of the extended drain region 225B The valence band electrons in the p+ drain region 230B from the filled energy level can thus tunnel through the depletion region to the empty energy level of the conduction band of the n-well NW body left more holes in the p+ drain region 230B and more electrons in the extended drain region 225B since the extended drain region 225B has a higher impurity concentration than in the n-well NW body. The holes are attracted to the wire connected with the drain 230B due to Vd(−). The electrons are mainly toward the selecting gate due to Vg( (0V or +) and the n-well NW body. On the way of electrons toward the selecting gate 210, a small cluster of electrons are captured by the nitride layer 220B of the right nonvolatile cell 205R by tunneling through the oxide layer. As the right nonvolatile cell 205R is desired to program as 0, the voltage exerted on it will be 0 V. In other words, the drain 230B served is like a bit line while programming the right nonvolatile cell 205R.

For reading the right nonvolatile cell 205R of the symmetrical pMOS based twin cell, a variety voltages Vs(−) , Vg(−), V_{B}(0), and Vd(0) exerted on the electrodes are shown in FIG. 2C. Since the twin cells 205L, 206R are controlled by the same selecting gate 210, thus, it is necessary to shield the left cell 205L while reading the right cell 205R so as to avoid the charges, or said datum stored in the nitride layer 220A, being interfered. The strategy of reading method is called “reverse read.” That is: to read the right cell 205R, the source 230A and the drain 230B are, respectively, exerted, as is shown in FIG. 2C so as to establish an electric field in between the n-well NW body and the source region 230A. The intensity of the electric field is. demanded to be large enough so that the depletion region 260 generated can enclose the source region 230A. Thus datum in the left cell 205L is safe. The chances of the right cell 205R interfering the datum in the left cell 206L are none.

On the other hand, as the left cell 205L is read, the voltages biased on the source electrode 230A, selecting gate 210, n-well body NW, and drain 230B are respectively, Vs(0) , Vg(−), V_{B}(0), and Vd(−). The depletion region established due to a reverse bias at the drain 230B and n-well NW body will shield the right cell 205R.

Still referring to FIG. 2C, assuming the nitride layer 220B of the right cell 205 had captured electrons and we are still focus on reading the right cell 205R. The voltages Vg(−) and Vs(−) exerted, respectively, on the selecting gate 210A and source 230A are required to be large enough so as to make sure the first channel 240 tapered and having its narrower end can touch the depletion boundary 260 so that the holes coming from the drain 230B passed through the first channel 240 can be accelerated by the electric field to the source electrode 230A if the third channel 242 can be generated due to the electrons in the nitride layer 220B if the nitride layer 220B of the right cell 205R has electrons therein. Accordingly, a hole current comes from the drain region 230B to source region 230A to be read. On the other hand, if the nitride layer 220B of the right cell 205 had none electrons, the third channel 242 in the extended drain region 225B is OFF. No current can be read.

To erase the data in the twin cells of the pMOS based twin cells, the methods of the data erasing includes (1) FN (Fowler-Nordheim) erase, as is shown in FIG. 2D; and (2) band to band hot hole injection, as is shown in FIG. 2E.

When the datum in the right cell 205R is desired to be erased by FN erase, the voltages exerted on the source electrode 230A, selecting gate 210, n-well body NW, and drain 230B are respectively, floating, Vg(−), Vd(+), and V_{B}(+). In the situation, the electron in the nitride layer 220B will be attracted by a Vd(+) exerted on the drain 220 R so as to approach the aim of pulling out the electrons.

When the datum in the right cell 205R is desired to be erased by band to band hot hole injection, the source electrode 230A is floating and the voltages are Vg(−), V_{B}(0 or +), and Vd(−), as is shown in FIG. 2E. Consequently, the drain 230B and the n-well body NW is reverse biased, as a result, an electric field is generated in between the drain 230B and n-well NW. The electric field generated due to a reverse bias can thus generate the electron-hole pairs in the extended drain region 220B, as aforementioned section about programming the right cell 205R. Since the selecting gate encounters a negative voltage bias rather than a positive voltage, the holes of the electron hole pairs are thus upward to the selecting gate 210, or drain 230B, and partly, are captured by the electrons in the nitride layer 220B of the right cell 205B to cause electron-hole recombination. If the nitride layer 220B has no electron, the chance of the holes injected into the nitride layer is almost zero. On the other hand, the electrons of the electron hole pairs are toward the n-well NW body.

The forgoing illustration is based on pMOS based twin nonvolatile cells. It is intended to cover various modifications and similar arrangements included within the spirit and scope of the appended claims, the scope of which should be accorded the broadest interpretation so as to encompass all such modifications and similar structure. For instance, the spirit and scope of the appended claims pMOS based twin cells should be expansion to an nMOS-based twin cells, as is shown in FIG. 3.

The structure of the nMOS-based twin cells is formed in the p-well includes: a selected gate 310, two sidewalls 310A, 310B, ONO spacers 220 having, respectively, a L-mirror and a L shaped nitride layer,320A, 320B, a p+ doped source 330A/drain region 330B, and an n doped extended source 325A/drain region 325B.

Since the conductivity of a pMOS is opposite to the nMOS, thus the operation method will be also opposite. For example, for programming the pMOS based twin cells, it is based on band to band hot electron injection, whereas for nMOS based twin cells, the principle is band to band hot hole injection. For erasing the pMOS based twin cells, the principle based on band to band hot hole injection, whereas for nMOS based twin cells, it is band to band hot electron injection.

Table 1 shows a comparison of voltage exerted on between pMOS based twin cells and nMOS based twin cells for reading, programming, and erase the right cell.

| | | pMOS based | nMOS based |
|---|---|---|---|
| | | twin cells | twin cells |
| programming | Source Vs | floating | floating |
| | selecting gate Vg | 0 V or +V | −V |
| | Drain Vd | −V | +V |
| | NW or PW body V_{B} | 0 V | −V |
| Reading | source Vs | −V | +V |
| | selecting gate Vg | −V | +V |
| | drain Vd | 0 V | 0 V |
| | NW or PW body V_{B} | 0 V | 0 V |
| Erase | Source Vs | floating | floating |
| method (1) | selecting gate Vg | −V | +V |
| | drain Vd | +V | −V |
| | NW or PW body V_{B} | +V | −V |
| Erase | source Vs | floating | floating |
| method (2) | selecting gate Vg | −V | +V |
| | drain Vd | −V | +V |
| | NW or PW body V_{B} | 0 V or +V | −V |

The benefits of this invention are:
(1) The PMOS based twin cells according to the present invention can double the memory capacity, for the same scaling technique is concerned.
(2) The fabricating processes are compatible with the analog CMOS processes.

As is understood by a person skilled in the art, the foregoing preferred embodiment of the present invention is an illustration of the present invention rather than limiting thereon. It is intended to cover various modifications and similar arrangements included within the spirit and scope of the appended claims, the scope of which should be accorded the broadest interpretation so as to encompass all such modifications and similar structure.

What is claimed is:

1. A MOS transistor based twin nonvolatile cells formed in the substrate having second conductivity type impurities lightly doped, said MOS transistor based twin cells comprising:
a selecting gate;
a pair of ONO spacers formed on the sidewalls of said MOS transistor, said ONO spacers having a L and L-mirror shaped nitride layer to store carriers therein;
a source/drain region having first conductivity type impurities heavily doped; and
an extended source/drain region doped with said second conductivity type impurities, the polarity of said first conductivity type being opposite to said second conductivity type.

2. The MOS transistor based twin nonvolatile cells according to claim 1 wherein said second conductivity type is an n-type and said first conductivity type is a p-type and said substrate is an n-well.

3. The MOS transistor based twin nonvolatile cells according to claim 2 wherein said MOS transistor based twin cells are programmed by a method of band to band hot electron injection.

4. The MOS transistor based twin nonvolatile cells according to claim 2 while reading a selected cell selected from said twin nonvolatile cells, the unselected cell is shielded by a depletion boundary, which is generated by a reverse bias associated with a first channel beneath said selecting gate generated due to a bias exerted on said selecting gate, and said first channel has a taper end connected to said depletion boundary so that a hole current can be read if a floating gate of the selected cell has electrons.

5. The MOS transistor based twin nonvolatile cells according to claim 2 while erasing the datum of a selected cell, a FN (Fowler_Nordheim) erase is taken so as to pull out the electrons in said nitride layer of a selected cell selected from said twin nonvolatile cells.

6. The MOS transistor based twin nonvolatile cells according to claim 2 while erasing the datum of a selected cell, a band to band hot hole injection is taken so as to inject holes to said nitride layer of said selected cell.

7. The MOS transistor based twin nonvolatile cells according to claim 1 wherein said second conductivity type is a p-type and said first conductivity type is an n-type and said substrate is a p-well.

8. The MOS transistor based twin nonvolatile cells according to claim 7 wherein said MOS transistor based twin cells are programmed by band to band hot hole injection.

9. The MOS transistor based twin nonvolatile cells according to claim 7 while reading a selected cell, the unselected cell is shielded by a depletion boundary, which is generated by a reverse bias associated with a first channel beneath said selecting gate generated due to a bias exerted on said selecting gate, and said first channel has a taper end connected to said depletion boundary so that an electron current can be read if a floating gate of the selected cell has holes.

10. The MOS transistor based twin nonvolatile cells according to claim 7 while erasing the datum of a selected cell, a FN (Fowler_Nordheim) erase is taken so as to pull out the holes in said nitride layer of said selected cell selected from said twin nonvolatile cells.

11. The MOS transistor based twin nonvolatile cells according to claim 7 while erasing the datum of a selected cell, a band to band hot electron injection is taken so as to inject electrons to said nitride layer of said selected cell.

12. A method of programming a MOS based twin nonvolatile cells according to claim 1, comprising a band to band hot electron injection to inject electrons to said nitride layer of a selected cell when said second conductivity type is n-type said selected cell selected from said twin nonvolatile cells.

13. A method of erasing a MOS based twin nonvolatile cells according to claim 1, comprising (1) a band to band hot hole injection to inject holes to said nitride layer of a selected cell when said second conductivity type is n-type, or (2). FN (Fowler_Nordheim) erase so as to pull out the electrons in said nitride layer of said selected cell when said second conductivity type is an n-type.

14. A method of reading a MOS based twin nonvolatile cells according to claim 1, comprising a reverse read said reverse read is to shield the unselected cell by a depletion boundary and the selecting gate and the electrode of said source/drain region in said unselected cell are biased so as to make sure a first channel beneath said selecting gate with its taper end connected to a second channel beneath the electrode of said source/drain region in said unselected cell so that if a floating gate of the selected cell has electrons, a hole current can be read while said second conductivity type is an n-type.
